(19) United States
(12) Patent Application Publication
(10) Pub. No.: US 2009/0110824 A1
(43) Pub. Date: Apr. 30, 2009

(54) Substrate processing apparatus and method of controlling substrate processing apparatus

(75) Inventors: Yuichi Takenaga, Nirasaki-shi (JP); Takahito Kasai, Nirasaki-shi (JP); Minoru Obata, Nirasaki-shi (JP); Yoshihiro Takezawa, Nirasaki-shi (JP); Kazuo Yabe, Nirasaki-shi (JP)

Correspondence Address: SMITH, GAMBRELL & RUSSELL, 1130 CONNECTICUT AVENUE, N.W., SUITE 1130, WASHINGTON, DC, 20036, US

(73) Assignee: Tokyo Electron Limited

(21) Appl. No.: 12/289,463

(22) Filed: Oct. 28, 2008

(30) Foreign Application Priority Data
Oct. 29, 2007 (JP) 2007-279897

(51) Int. Cl. C23C 16/44; C23C 16/54

(52) U.S. Cl. 427/248.1; 118/724

(57) ABSTRACT

In accordance with a set temperature profile including: a first step in which a temperature is varied from a first temperature to a second temperature during a first time period; a second step in which the temperature is maintained at the second temperature during a second time period; and a third step in which the temperature is varied from the second temperature to a third temperature; a substrate is subjected to a film deposition process. The first temperature, the second temperature, and the third temperature are determined based on the first relationship between temperature and film thickness, the measured film thicknesses at the plurality of positions, and a predetermined target film thickness. There are calculated expected film thicknesses at a plurality of positions on a substrate to be actually processed in accordance with the set temperature profile corresponding to the determined first temperature, the determined second temperature, and the determined third temperature. When the expected film thicknesses at the plurality of positions are not within a predetermined allowable range with respect to the predetermined target film thickness, at least one of the first time period, the second time period, and the third time period is varied.

### FIELD OF THE INVENTION

The present invention relates to a substrate processing apparatus and a method of controlling a substrate processing apparatus.

### BACKGROUND ART

In a manufacturing process of a semiconductor, there is used a substrate processing apparatus that processes a semiconductor wafer as a substrate (hereinafter referred to as “wafer”). For example, a vertical heat processing apparatus is used as the substrate processing apparatus. In the vertical heat processing apparatus, a holder capable of holding a number of wafers in a tier-like manner is located in a vertical heat processing furnace, and films are formed on the substrates by a CVD (Chemical Vapor Deposition) process, an oxidation process, and so on.

When wafers are subjected to a film deposition process by the substrate processing apparatus, uniformity of film thickness on the wafer(s) is important. In order to improve the uniformity of the film thickness, there has been developed a method in which films are deposited while a temperature is varied. (See, for example, JP2002-110552A. In particular, Section 0099.) By varying a temperature during the film deposition process, a temperature distribution on the wafers is controlled, so that a film thickness distribution can be made uniform. To be specific, with the use of a suitable set temperature profile, a favorable film thickness distribution can be obtained.

However, it is not always easy to select a suitable set temperature profile.

### SUMMARY OF THE INVENTION

The present invention has been made under the above circumstances. The object of the present invention is to provide a substrate processing apparatus that is capable of facilitating determination of a suitable set temperature profile, and a method of controlling such a substrate processing apparatus.

The present invention is a substrate processing apparatus comprising:

a storage part that stores a set temperature profile including:
a first step in which a temperature is varied from a first temperature to a second temperature during a first time period;
a second step in which the temperature is maintained at the second temperature during a second time period; and
a third step in which the temperature is varied from the second temperature to a third temperature;

a substrate processing part that deposits a film on a substrate, by heating the substrate in accordance with the set temperature profile and by supplying a process gas in the third step;

a first derivation part that derives a first relationship between temperature and film thickness which is a corresponding relationship between a variation amount of temperature and variation amounts of film thicknesses at a plurality of positions on a substrate, when the substrate is processed in accordance with a varied temperature profile in which at least one of the first temperature, the second temperature, and the third temperature is varied;

an input part to which measured film thicknesses at the plurality of positions on the substrate that has been actually processed by the substrate processing part in accordance with a predetermined set temperature profile are inputted;

a first determination part that determines the first temperature, the second temperature, and the third temperature, based on the first relationship between temperature and film thickness, the measured film thicknesses at the plurality of positions, and a predetermined target film thickness;

an expected film-thickness calculation part that calculates expected film thicknesses at a plurality of positions on a substrate to be actually processed in accordance with the set temperature profile corresponding to the determined first temperature, the determined second temperature, and the determined third temperature;

a second derivation part that varies at least one of the first time period, the second time period, and the third time period, under predetermined circumstances, and that derives a second relationship between temperature and film thickness which is a corresponding relationship between a variation amount of temperature and variation amounts of film thicknesses at the plurality of positions on the substrate, when the substrate is processed in accordance with a further varied temperature profile in which one of the first temperature, the second temperature, and the third temperature is varied; and

a second determination part that redetermines the first temperature, the second temperature, and the third temperature, based on the second relationship between temperature and film thickness, the measured film thicknesses at the plurality of positions, and the predetermined target film thickness.

According to the present invention, determination of a suitable set temperature profile can be significantly made easier.

Preferably, the predetermined circumstances are circumstances in which the expected film thicknesses at the plurality of positions are not within a predetermined allowable range with respect to the predetermined target film thickness.

In addition, for example, the storage part stores a plurality of set temperature profiles. In this case, the substrate processing part includes a holding part that can hold a plurality of substrate in a tier-like manner, and a plurality of heating parts whose heat values can be controlled in accordance with the respective set temperature profiles.

In this case, preferably, the first derivation part is configured to derive the first relationship between temperature and film thickness which is a corresponding relationship between a variation amount of temperature and variation amounts of film thicknesses at a plurality of positions on a substrate, when the substrate is processed in accordance with a plurality of varied temperature profiles in any of which at least one of the first temperature, the second temperature, and the third temperature is varied; the input part is configured such that measured film thicknesses at the plurality of positions on a plurality of substrates respectively corresponding to the plurality of heating parts are inputted, the substrates having been actually processed by the substrate processing part in accordance with the plurality of predetermined set temperature profiles; and the first determination part is configured to determine the first temperature, the second temperature, and the third temperature of each of the plurality of set temperature profiles, based on the first relationship between temperature and film thickness, the measured film thicknesses at the plurality of positions on the plurality of substrates; and the predetermined target film thickness.

In addition, for example, the first derivation part includes: a first calculation part that calculates first expected film thicknesses at the plurality of positions, when the substrate is processed in accordance with a set temperature profile in which the first temperature is varied; a second calculation part that calculates second expected film thicknesses at the plurality of positions, when the substrate is processed in accordance with another set temperature profile in which the second temperature is varied; a third calculation part that calculates third expected film thicknesses at the plurality of positions, when the substrate is processed in accordance with another set temperature profile in which the third temperature is varied; a fourth calculation part that calculates fourth expected film thicknesses at the plurality of positions, when the substrate is processed in accordance with the original set temperature profile in which none of the temperatures is varied; and a difference calculation part that calculates a difference between each of the first to third expected film thicknesses and the fourth expected film thicknesses.

Alternatively, the present invention is A method of controlling a substrate processing apparatus that deposits a film on a substrate by heating the substrate in accordance with a set temperature profile including: a first step in which a temperature is varied from a first temperature to a second temperature during a first time period; a second step in which the temperature is maintained at the second temperature during a second time period; and a third step in which the temperature is varied from the second temperature to a third temperature; and by supplying a process gas in the third step, the method comprising the steps of:

deriving a first relationship between temperature and film thickness which is a corresponding relationship between a variation amount of temperature and variation amounts of film thicknesses at a plurality of positions on a substrate, when the substrate is processed in accordance with a varied temperature profile in which at least one of the first temperature, the second temperature, and the third temperature is varied;

inputting measured film thicknesses at the plurality of positions on the substrate that has been actually processed in accordance with the predetermined set temperature profile;

determining the first temperature, the second temperature, and the third temperature, based on the first relationship between temperature and film thickness, the measured film thicknesses at the plurality of positions, and a predetermined target film thickness;

calculating expected film thicknesses at a plurality of positions on a substrate to be actually processed in accordance with the set temperature profile corresponding to the determined first temperature, the determined second temperature, and the determined third temperature;

varying at least one of the first time period, the second time period, and the third time period, under predetermined circumstances, and then deriving a second relationship between temperature and film thickness which is a corresponding relationship between a variation amount of temperature and variation amounts of film thicknesses at the plurality of positions on the substrate, when the substrate is processed in accordance with a further varied temperature profile in which one of the first temperature, the second temperature, and the third temperature is varied; and

redetermining the first temperature, the second temperature, and the third temperature, based on the second relationship between temperature and film thickness, the measured film thicknesses at the plurality of positions, and the predetermined target film thickness.

According to the present invention, determination of a suitable set temperature profile can be significantly made easier.

Preferably, the predetermined circumstances are circumstances in which the expected film thicknesses at the plurality of positions are not within a predetermined allowable range with respect to the predetermined target film thickness.

Alternatively, the present invention is a storage medium storing a computer program operable on a computer, the computer program including steps to implement the method of controlling a substrate processing apparatus having the aforementioned features.

### BRIEF DESCRIPTION OF THE DRAWINGS

FIG. 1 is a schematic sectional view showing a substrate processing apparatus in one embodiment of the present invention.

FIG. 2 is a graph showing an example of a set temperature profile.

FIG. 3 is a flowchart showing an example of a procedure for operating the substrate processing apparatus.

FIG. 4 is a table showing an example of process conditions to be inputted.

FIG. 5 is a table showing an example of a relationship between temperature and film thickness.

FIG. 6 is a table showing combinations of varied set time periods.

### BEST MODE FOR CARRYING OUT THE INVENTION

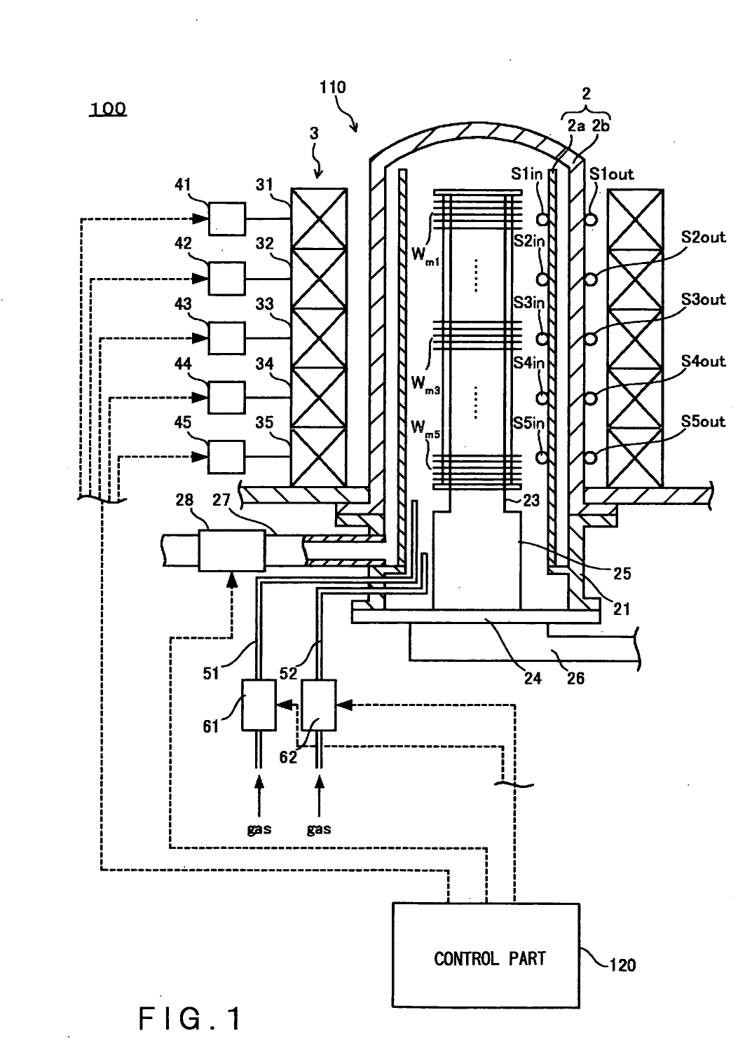

An embodiment of the present invention will be described in detail below with reference to the drawings. FIG. 1 is a schematic sectional view showing a substrate processing apparatus 100 in one embodiment of the present invention. The substrate processing apparatus 100 is composed of a substrate processing part 110 and a control part 120. In FIG. 1, the substrate processing part 110 is formed of a so-called vertical heat processing apparatus. FIG. 1 schematically shows a longitudinal section thereof.

The substrate processing part 110 is provided with a reaction tube 2 of a dual tube structure including an inner tube 2a and an outer tube 2b that are made of quartz, for example. A cylindrical metal manifold 21 is disposed on a lower part of the reaction tube 2.

An upper end of the inner tube 2a is opened, while a lower end thereof is supported by an inner end of the manifold 21. An upper end of the outer tube 2b is closed, while a lower end thereof is hermetically joined to an upper end of the manifold 21.

In the reaction tube 2, there is located a wafer boat 23 as a holder. The wafer boat 23 is held on a lid member 24 via a heat retention tube (heat insulation member) 25. A number of wafers W (product wafers Wp and monitor wafers Wm1 to Wm5) as substrates are placed in the wafer boat 23.

The lid member 24 is arranged on an upper surface of a boat elevator 26 that is used for loading and unloading the wafer boat 23 to and from the reaction tube 2. At an upper limit position, the lid member 24 is adapted to close a lower end opening of the manifold 21, i.e., a lower end opening of a process vessel composed of the reaction tube 2 and the manifold 21.

Around the reaction tube 2, there is provided a heater 3 formed of, e.g., a heating resistor. The heater 3 is divided into five elements, i.e., heating elements 31 to 35. The heating elements 31 to 35 are configured to be controlled by power controllers 41 to 45, respectively, such that heating values of the respective heating elements 31 to 35 can be independently controlled. In this embodiment, the reaction tube 2, the manifold 21, and the heater 3 constitute a heating furnace.

Arranged on an inner wall of the inner tube 2a are inner temperature sensors S1in to S5in such as thermocouples, so as to correspond to the heating elements 31 to 35. Further, arranged on an outer wall of the outer tube 2b are outer temperature sensors S1out to S5out such as thermocouples, so as to correspond to the heating elements 31 to 35.

Correspondingly to the heating elements 31 to 35, an inside of the inner tube 2a can be supposed to be divided into five zones (zones 1 to 5). Note that, however, the plurality of wafers placed in the wafer boat 23 in the reaction tube 2 constitute one batch as a whole, and the wafers are thermally processed together (at the same time).

In this example, the monitor wafers Wm1 to Wm5 are arranged so as to correspond to the respective zones 1 to 5. However, in general, it is not necessary that the number of zones and the number of monitor wafers Wm correspond to each other. For example, ten or three monitor wafers Wm may be arranged for five zones. Even when the number of zones and the number of monitor wafers Wm do not correspond to each other, it is possible to optimize a set temperature profile.

In order to supply a gas into the inner tube 2a, a plurality of gas supply pipes are connected to the manifold 21. Two gas supply pipes 51 and 52 are shown in FIG. 1 as a matter of convenience. Disposed in the respective gas supply pipes 51 and 52 are flow-rate adjusting parts 61 and 62, such as massflow controllers for adjusting flow rates, and valves (not shown).

In addition, connected to the manifold 21 is an exhaust pipe 27 through which air is discharged from a gap between the inner tube 2a and the outer tube 2b. The exhaust pipe 27 is connected to a vacuum pump, not shown. A pressure adjusting part 28 for adjusting a pressure in the reaction tube 2, which includes a butterfly valve and a valve driving part, for example, is disposed on the exhaust pipe 27.

The control part 120 has a function for controlling process parameters such as a temperature of a process atmosphere in the reaction tube 2, a pressure of the process atmosphere in the reaction tube 2, a gas flow rate, and so on. Inputted to the control part 120 are measurement signals from the temperature sensors S1in to S5in and S1out to S5out. The control part 120 outputs control signals to the power controllers 41 to 45 of the heater 3, the pressure adjusting part 28, and the flow-rate adjusting parts 61 and 62.

The control part 120 is formed of, e.g., a computer, and thus includes a central processing unit (CPU), an input and output device, and a storage device. The control part 120 is controlled by a program so as to realize functions of following parts 1) to 5).

1) A storage part storing a set temperature profile
2) A derivation part that derives a relationship between temperature and film thickness
3) An input part to which a measured film thickness of a substrate is inputted
4) A determination part that determines first to third temperatures (temperatures T1 to T3)
5) An expected film-thickness calculation part that calculates an expected film thickness of a substrate (wafer W)

Based on the set temperature profiles, the control part 120 controls the power controller 41 to 45. Thus, wafers W are heated by the heating elements 31 to 35. Herein, the set temperature profile sets forth a relationship between an elapse of time and a set temperature (temperature at which the wafer W should be).

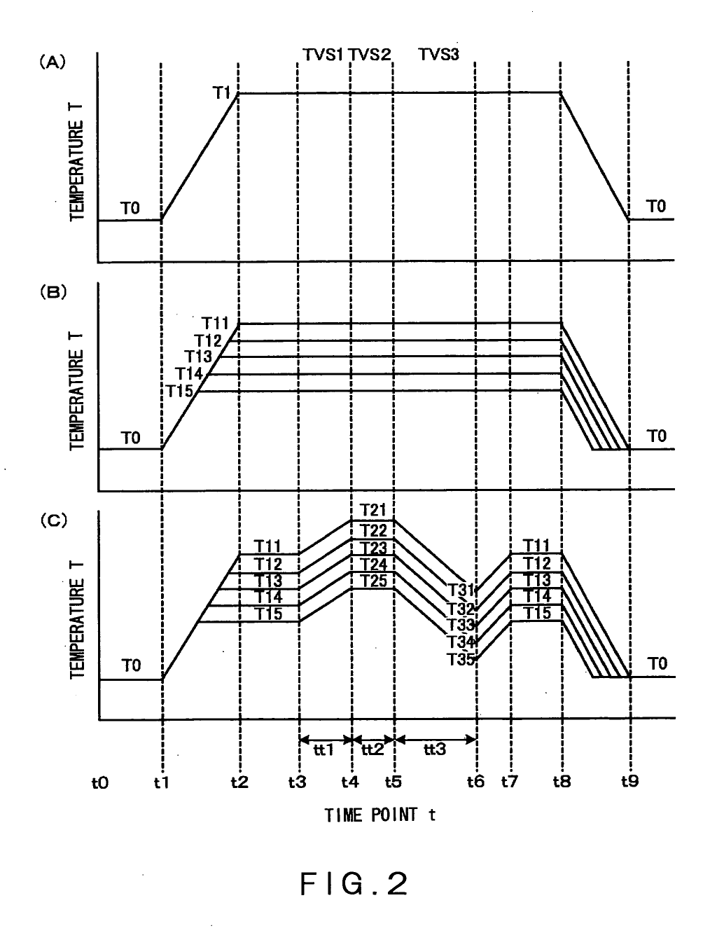

FIG. 2 is a graph showing an example of a set temperature profile being a relationship between time and temperature. Each of (A) to (C) in FIG. 2 is a set temperature profile as described below.

### (A) Fixed Temperature Process 1

This is a profile in which a set temperature is fixed (constant) during a time period TVS3, during which wafers W are processed, and also during certain time periods prior to and posterior to the time period TVS3, and in which set temperatures for the zones 1 to 5 are the same.

### (B) Fixed Temperature Process 2

This is a profile in which a set temperature is fixed during the time period TVS3, during which wafers W are processed, and also during certain time periods prior to and posterior to the time period TVS3, while set temperatures for the zones 1 to 5 differ from each other. With a view to making uniform film thicknesses between the wafers W (monitor wafers Wm1 to Wm5) (to make uniform a film thickness distribution between wafers), the set temperatures of the zones 1 to 5 are made different.

Wafers W are generally processed by the above (A) profile (fixed temperature process 1) or the above (B) profile (fixed temperature process 2).

### (C) Varied Temperature Process

This is a profile in which a set temperature is varied during the time period TVS3, during which wafers W are processed, and set temperatures for the zones 1 to 5 differ from each other. With a view to making uniform a film thickness on each wafer W (to make uniform a film thickness distribution within a wafer), the temperature is varied during the process time period of wafers W (TVS3) so as to control a temperature distribution on the wafer W. Temperature control before the wafers W are processed (during time periods TVS1 and TVS2) also contributes to the control of the temperature distribution on the wafer W. In addition, with a view to making uniform a film thickness distribution between wafers, the set temperatures for the zones 1 to 5 are made different.

Herebelow, details of the set temperature profile (C) are described.

(1) From a time point t0 to a time point t1, a set temperature is maintained at T0. At this time, the wafer boat 23 holding wafers W is loaded into the substrate processing part 110 (loading step).
(2) Between the time point t1 and a time point t2, the set temperature is increased at a constant rate from the temperature T0 to a temperature T1 (T11 to T15) (temperature increase step). Note that the temperatures T11 to T15 differ from each other depending on the zones 1 to 5. Thus, a finish time point of the temperature increase step somewhat varies from zone to zone.
(3) Between the time point t2 and a time point t3, the set temperature is unchanged and maintained at T1 (T11 to T15). This is because, even after the set temperature has been fixed, it takes some time for an actual temperature of the wafer W to become constant, because of a thermal inertia. That is, until the temperature of the wafer is stabilized, the method does not proceed to the next step (stabilizing step).
(4) A time period from the time point t3 to a time point 5 is used as a preparatory step for a film deposition, for finely adjusting a temperature distribution upon film deposition. Conversely, the set temperature profile from the time point t3 to the time point t5 has a great impact on the temperature distribution upon film deposition.

1) Between the time point t3 and a time point t4, the set temperature T1 (T11 to T15) is increased at a constant rate up to a temperature T2 (T21 to T25) (TVS1: temperature increase step).

2) In the example (C), between the time point t4 and the time point t5, the set temperature is unchanged and maintained at the temperature T2 (T21 to T25) (TVS2: fixed temperature step). However, the step TVS2 may be replaced with a varied temperature step (temperature increase step or temperature decrease step). In other words, between the time point t4 and the time point t5, the set temperature may be varied from the temperature T2 to a temperature T2′. (In this case, the subsequent step TVS3 starts not from the temperature T2 but from the temperature T2′.)

(5) Between the time point t5 and a time point t6, the set temperature is decreased at a constant rate from the temperature T2 (T21 to T25) to a temperature T3 (T31 to T35). During this time period, process gases such as SiH₂Cl₂ and NH₃ are introduced from the gas supply pipes 51 and 52 into the substrate processing part 110, so that an SiN film is deposited by the CVD (TVS3: temperature decrease/film deposition step).
(6) A time period from the time point t6 to a time point t8 is used as a time period in which the temperature of the wafer W is returned to the temperature T1 (T11 to T15).

1) Between the time point t6 and a time point t7, the set temperature is increased at a constant rate from the temperature T3 (T31 to T35) to the temperature T1 (T11 to T15) (temperature increase step).

2) Between the time point t7 and the time point t8, the set temperature is unchanged and maintained at the temperature T1 (fixed temperature step).

(7) Between the time point t8 and a time point t9, the set temperature is decreased at a constant rate from the temperature T1 (T11 to T15) to the temperature T0 (temperature decrease step). Since the temperatures T11 to T15 differ from each other depending on the zones 1 to 5, a finish time point of the temperature decrease step somewhat varies from zone to zone.
(8) After the time point t9, the set temperature is maintained at T0. After the time point t9, the wafer boat 23 holding the wafers W is unloaded from the substrate processing part 110 (unloading step).

In the aforementioned set temperature profile (C), the time period(s) from the time point t3 to the time point t6 (from step TVS1 to step TVS3) is important. The set temperature profile from the step TVS1 to the step TVS3 may be defined by the temperature T1 (T11 to T15), the temperature T2 (T21 to T25), the temperature T3 (T31 to T35), a time period tt1 (=t4−t3), a time period tt2 (=t5−t4), and a time period tt3 (=t6−t3).

The step TVS3 is the film deposition step, and produces a greatest effect on a film thickness and a film thickness distribution of the wafer W. When the temperature T2, the temperature T3, and the time period tt3 are varied, a distribution of a time-average temperature on the wafer W is varied, so that the film thickness and the film thickness distribution of the wafer W are varied.

A film thickness distribution in a plane of the wafer W appears because of a temperature distribution in the wafer plane and/or a concentration distribution of a process gas in the wafer plane. Irrespective of the reason, by controlling the temperature distribution in the plane of the wafer W, it is possible to make uniform a film thickness distribution.

For example, a temperature of the wafer W differs between an edge portion and a center portion of the wafer W. Since the edge portion of the wafer W is nearer to an outside of the wafer W (such as heater 3), the edge portion is easy to be heated and cooled. On the other hand, the center portion of the wafer W is away from the outside of the wafer W, the center portion is difficult to be heated and cooled. Thus, in the temperature decrease step, the temperature at the edge portion of the wafer W is firstly decreased as compared with the temperature at the center portion. As a result, in the temperature decrease step, there is a tendency that the temperature (time-average temperature) at the edge portion of the wafer W is lower than the temperature (time-average temperature) at the center portion of the wafer W. Thus, by varying sign (positive/negative) and degree of a rate at which the temperature is varied, sign (positive/negative) and degree of the temperature distribution on the wafer W can be adjusted.

Meanwhile, the step TVS1 and the step TVS2 also have an effect on the film thickness of the wafer W. This is because, when the step TVS1 and the step TVS2 (temperature T1, time period tt1, time period tt2) are changed, the temperature distribution of the wafer W upon the film deposition (in particular, at the beginning of the film deposition) is varied. As compared with the step TVS3, the step TVS1 and the step TVS2 have a larger degree of freedom in changing themselves, and thus it is easier to utilize the steps TVS1 and TVS2 for controlling the film thickness distribution. (Since the step TVS3 is nothing but a film deposition process, a degree of freedom in changing the step TVS3 is limited in relation to a target film thickness Dt.)

As described above, the set temperature profile directly specifies a temperature in accordance with an elapse of time. In addition thereto, various other manners are possible. For example, the set temperature profile may specify a ratio at which the temperature is varied, such as a temperature increase rate, or may specify a heater output. As long as an elapse of time and a temperature of the wafer W are related to each other, there is no limitation in specifying a certain factor.

The set temperature profile is a part of a process recipe that decides an overall heat process of the wafer W. In addition to the set temperature profile, the process recipe generally specifies a step of discharging gas(es) from the substrate processing part 110 and/or a step of introducing a process gas thereinto, in accordance with an elapse of time. (Procedure for Operating Substrate Processing Apparatus 100)

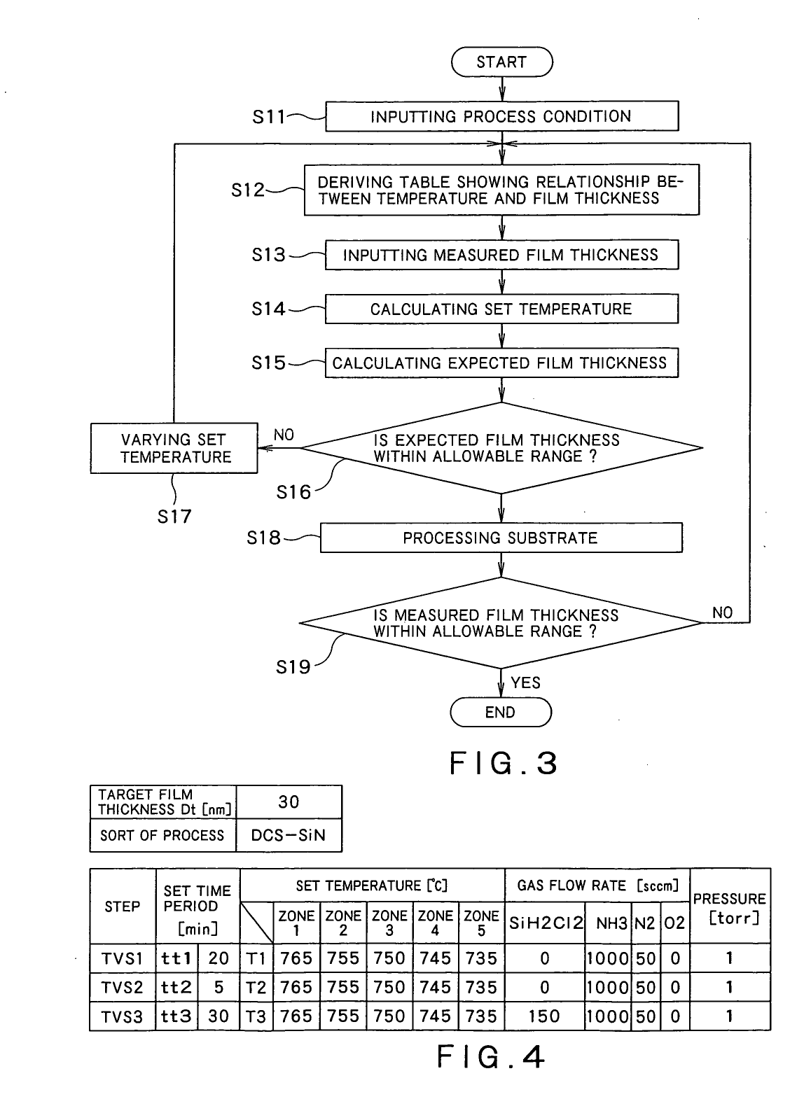

Next, an example of a procedure for operating the substrate processing apparatus 100 is described. FIG. 3 is a flowchart showing an example of a procedure for operating the substrate processing apparatus 100.

Herein, it is supposed that, after wafers W have been processed in accordance with the fixed temperature process 2 (FIG. 2(B)), the wafers W are further processed in accordance with the varied temperature process (FIG. 2(C)) in which the set temperatures T1 (T11 to T15) to T3 (T31 to T35) and the set time periods tt1 to tt3 are adjusted. It is important to obtain the temperatures T1 (T11 to T15) to T3 (T31 to T35) and the time periods tt1 to tt3 that allow uniformity of film thicknesses between wafers and also uniformity of film thickness within each wafer plane.

### A. Input of Process Condition (Step S11)

As shown in FIG. 3, process conditions are inputted in the first place. FIG. 4 shows an example of process conditions to be inputted. As shown in FIG. 4, inputted to the control part 120 are (1) target film thickness Dt and (2) recipe used in the former process.

### (1) Target Film Thickness Dt

A target film thickness Dt [nm] for a wafer W is inputted. The target film thickness Dt is a target value of the film thickness of the wafer W. In this example, the target film thickness Dt is the same (common) on all the positions of all the wafers W. However, the target film thickness Dt may not be the same for all the wafers W. For example, by dividing the wafers W into a plurality of groups, different target film thicknesses Dt can be set for the respective groups (or the respective wafers W).

### (2) Recipe Used in Former Process (Set Time Period, Set Temperature, Gas Flow Rate, Pressure)

A set time period or the like is inputted for each of the steps TVS1 to TVS3. The set time period [min] is each of the time periods tt1 to tt3 of the steps TVS1 to TVS3. A set temperature [° C.] is each of the set temperatures T1 (T11 to T15) to T3 (T31 to T35) of the zones 1 to 5. The temperatures T1 to T3 are fixed (corresponding to the fixed temperature process 2 (FIG. 2(B)). Only in the step TVS3, the flow rate of SiH₂Cl₂ is not zero. Thus, only in the step TVS3, a film is deposited. A gas flow rate [sccm] is defined for each kind of a reaction gas (e.g., SiH₂Cl₂, NH₃, N₂, or O₂). A pressure [Torr] is a total pressure.

B. Derivation of Relationship between Temperature and Film Thickness (step S12)

Then, in accordance with the following steps (1) and (2), a relationship between temperature and film thickness (a first relationship between temperature and film thickness) is derived. The relationship between temperature and film thickness is a corresponding relationship between a variation amount of temperature and a variation amount of film thickness of a wafer W, when the wafer W is processed in accordance with a varied temperature profile in which one of the temperatures T1 (T11 to T15) to T3 (T31 to T35) is varied.

### (1) Calculation of Expected Film Thickness Dij

An expected film thickness Dij (Tkl+ΔTkl) when one (Tkl) of the temperatures T1 (T11 to T15) to T3 (T31 to T35) is raised by 1° C. (ΔTkl) is calculated. Herein, film thicknesses at two positions (center portion and edge portion) are expected for the respective monitor wafers Wm1 to Wm5. Parameters i to l have meanings as described below.

i (=1 to 5): a parameter for identifying each of the monitor wafers Wm1 to Wm5

j (=1, 2): a parameter for identifying a position on the substrate, in which 1 represents a center portion of the substrate and 2 represents an edge portion of the substrate

k (=1 to 3): a parameter for identifying a varied object (one of the temperatures T1 to T3)

l (=1 to 5): a parameter for identifying each of zones 1 to 5

In this embodiment, fifteen sets of expected film thicknesses Dij are calculated correspondingly to the five zones 1 to 5 and the temperatures T1 to T3. In addition, an expected film thickness Dij (Tkl) in the case of a set temperature profile that has not been varied is also calculated. Details of a method of calculating an expected film thickness D is described hereafter.

### (2) Calculation of Difference ΔDij Between Film Thicknesses

There is calculated a difference ΔDij between the expected film thickness Dij (Tkl+ΔTkl) when one of the temperatures T1 to T3 is varied, and the expected film thickness Dij (Tkl) when none of the temperatures T1 to T3 is varied.

ΔDij=Dij(Tkl+ΔTkl)−Dij(Tkl)

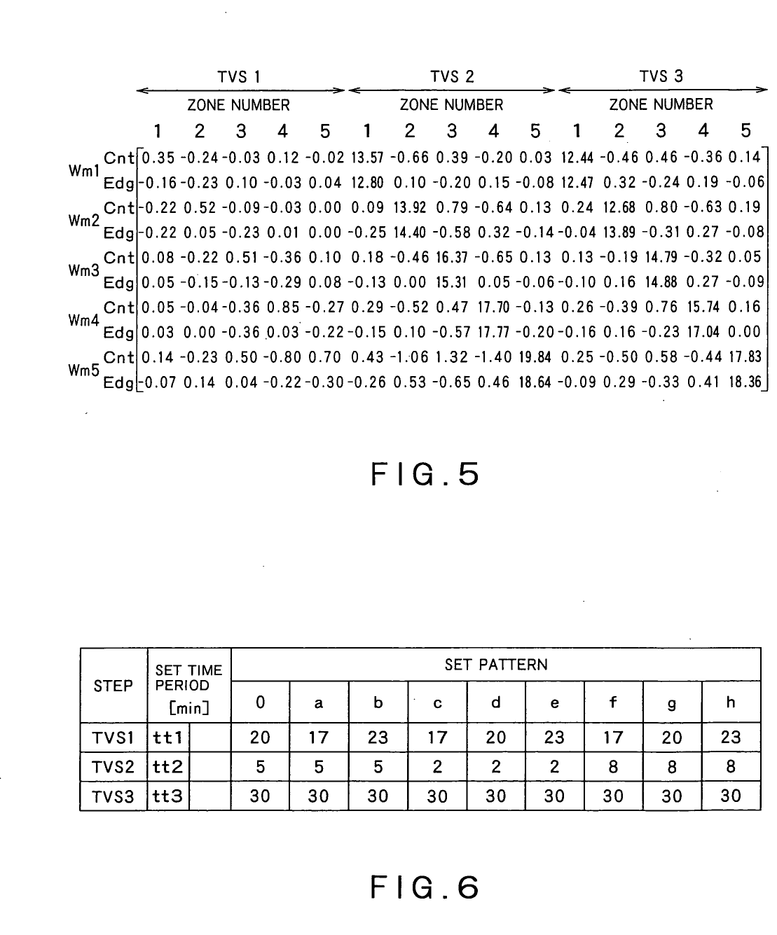

This differential value ΔDij represents a corresponding relationship (relationship between temperature and film thickness) between a variation amount of the temperature and a variation amount of the film thickness of the substrate. The differential values ΔDij can be sorted in a matrix or the like. FIG. 5 shows an example of the derived relationship between temperature and film thickness.

### (3) Details of Method of Calculating Expected Film Thickness D

Details of the method of calculating the expected film thickness D are described. In order to calculate the expected film thickness D, the substrate temperature is estimated at first, as described in the following items 1) and 2). A film thickness is calculated with the use of the estimated substrate temperature.

1) Estimation of Temperature on Wafer W

Based on the set temperature profile, the control part 120 estimates, for the respective monitor wafers Wm1 to Wm5, temperatures at a center portion (center temperatures) Tc1 to Tc5 and temperatures at an edge portion (edge temperatures) Te1 to Te5.

The following expressions (1) and (2), which are known in the control engineering, are used for this estimation.

x(t+1)=A·x(t)+B·u(t) Expression (1)

y(t)=C·x(t)+u(t) Expression (2)

in which

t: time period,

x(t): n-dimensional state vector,

y(t): m-dimensional output vector,

u(t): r-dimensional input vector, and

A, B, C: constant matrixes of n×n, n×r, and m×n, respectively.

Expression (1) is called state equation, and Expression (2) is called output equation. By simultaneously solving Expressions (1) and (2), the output vector y(t) corresponding to the input vector u(t) can be calculated.

In this embodiment, the input vector u(t) falls under the set temperature profile, and the output vector y(t) falls under the center temperatures Tc1 to Tc5 and the edge temperatures Te1 to Te5.

In Expressions (1) and (2), the set temperature profile has a multi input-output relationship with the center temperature Tc and the edge temperature Te. That is, each of the heating elements 31 to 35 (zones 1 to 5) of the heater 3 does not independently affect each of the monitor wafers Wm1 to Wm5, but each of the heating elements 31 to 35 affects every monitor wafer in one way or another.

After a combination of the constant matrixes A, B and C has been determined, Expressions (1) and (2) are simultaneously solved. Then, the center temperatures Tc1 to Tc5 and the edge temperatures Te1 to Te5 can be calculated from the set temperature profile. The constant matrixes A, B and C are determined by heat characteristics of the substrate processing part 110. As a method for obtaining them, a subspace method can be applied, for example.

Alternatively, in place of the aforementioned method, a method such as a Kalman filter may be used.

2) Calculation of Film Thickness

In an interface rate-determining process in which a film deposition rate is determined by a process that is performed on the surface of a film, such as a CVD (chemical Vapor Deposition) process, it is known that a growth rate of the film thickness (film deposition rate) V is represented by a theoretical equation (Arrhenius' equation) of the following Expression (3).

V=C·exp(−Ea/(kT)) Expression (3)

in which

C: process constant (constant determined by a film deposition process),

Ea: activation energy (constant determined by a kind of the film deposition process),

k: Boltzmann's constant, and

T: absolute temperature.

For example, in a case in which an SiN film is deposited from reaction gases SiH₂Cl₂ and NH₃, Ea=1.8 [eV].

By substituting the activation energy Ea and the absolute temperature T (estimated center temperature Tc and estimated edge temperature Te) into Expression (3), the film deposition rate V at the center portion and also the film deposition rate V at the edge portion of the wafer are determined. By performing a time quadrature to the film deposition rate V, a film thickness value (expected film thickness Dij) can be calculated.

Herein, the film deposition rate V is calculated by means of Expression (3). Namely, it is assumed that the Arrhenius' equation is satisfied. However, depending on process conditions and/or apparatus conditions, there is a possibility that the Arrhenius' equation may have some error, because a value to be substituted for the activation energy Ea may not be optimum. In order to correct the error, a learning function can be adopted. That is, by repeating calculation with the use of actually measured values so as to understand a relationship between the actual temperature and the actual film thicknesses, parameters used in the calculation can be finely adjusted in accordance with the relationship. The Kalman filter may be used in this learning function. This learning function may be added to any of the steps S12 and S14.

### C. Input of Measured Film Thickness (Step S13)

There are inputted measured values D0ij of thicknesses of films deposited at the center portions and the edge portions of the monitor wafers Wm1 to Wm5 which have been processed in accordance with the predetermined set temperature profile (herein, profile of (B) fixed temperature process 2).

In order to measure the film thickness, a film-thickness measuring device such as an ellipsometer may be used. As the measured value D0ij, an actual measured value of the film thickness at the center portion/edge portion may be used. However, in place thereof, a film thickness at the center portion/edge portion may be obtained by a calculation based on thicknesses measured at a plurality of positions on the wafer W. By using various calculations, a more precise value can be utilized as a film thickness at the center portion/edge portion.

For example, a film thickness is measured at nine points (one point at the center portion, four points at the edge portion, and four points between the center and the edge) on one wafer W, an expression conforming to the measurement result (for example, the following Expression (10)) may be obtained. Expression (10) is a model expression that represents the film thickness D on a wafer surface as a quadratic function of a distance x from the center of the wafer.

D=a·x²+b Expression (10)

in which

a and b: constants.

The constants a and b can be calculated by using a least squares method. Thus, the film thicknesses D0ij at the center portion and the edge portion of the wafer W can be calculated.

### D. Calculation of Set Temperature (Step S14)

The set temperatures T1 (T11 to T15) to T3 (T31 to T35) can be calculated in accordance with the following procedure. As described above, the learning function may be added to the step S14.

1) Calculation of Difference (film thickness difference) ΔD0ij between Measured Film Thickness D0ij and Target film thickness Dt

The difference can be derived from the following expression.

ΔD0ij=D0ij−Dt

2) Calculation of Temperature Variation Amount ΔTkl

Based on the film thickness difference ΔD0ij, a variation amount of the set temperature (temperature variation amount) ΔTkl can be calculated. In order to vary the expected film thickness Dij by the film thickness difference ΔD0ij, the following Expression (20) has to be satisfied. On the other hand, as shown in Expression (21), for example, a realistic value range of the temperature variation amount ΔTkl may be set.

ΔD0ij=Σ(ΔDij(Tkl)*ΔTkl) Expression (20)

−AΔ<ΔTkl<ΔT Expression (21)

Herein, ΔT is 50° C., for example. Expression (20) is a kind of linear approximation, and the valid range (conforming to the actual value) is not always wide. Thus, it is effective that the range is limited by Expression (21). In addition, such limitation of temperature range is effective in terms of film quality as well. That is, when the process temperature for the wafer W exceeds a predetermined range, a desired film (of a desired film quality) may not be deposited on the wafer W, to thereby invite a defect in a manufactured semiconductor device.

Since Expression (20) itself is a simultaneous linear equation in which the number of temperature variation amounts Δkl to be obtained is fifteen and the number of expressions is ten, combination of the temperature variation amounts ΔTkl can be obtained. However, in consideration of the limitation of Expression (21), there is a possibility that no solution might exist. Thus, it is effective to calculate the temperature variation amount ΔTkl by the following method. Namely, under the conditions of Expression (21), there is calculated the temperature variation amount ΔTkl which minimizes the following amount S. The amount S is an amount meaning a root mean square of the target film thickness Dt and the film thickness difference.

S=Σ(ΔD0ij−Σ(ΔDij(Tkl)*ΔTkl))² Expression (22)

3) Calculation of Set Temperature Tkl

After the temperature difference ΔTkl has been calculated as described above, by representing the set temperature Tkl used in the former process (process in accordance with the profile (B) fixed temperature process 2) as T0kl, a set temperature T1kl for the subsequent process can be calculated from the following Expression (23).

T1kl=T0kl+ΔTkl Expression (23)

### E. Calculation of Expected Film Thickness D1ij (Step S15)

Then, expected film thicknesses D1ij at the set temperature T1kl are calculated.

Similarly to the aforementioned method, a temperature on the wafer W is estimated, and then the expected film thicknesses D1ij are calculated.

F. Judgment of whether Expected Film Thickness is within Allowable Range or Not, and Varying of Set Time Periods tt1 to tt3 (Steps S16 and 17)

It is judged whether the expected film thicknesses D1ij are within a predetermined allowable range (uniformity) or not (step S16). For example, it is judged whether all or a part of |D1ij−Dt| are equal to or less than an allowable amount Th or not.

|D1ij−Dt|<Th Expression (24)

When the expected film thicknesses D1ij are not within the allowable range, the set time period is varied, and the steps S12 to S16 are repeated.

For example, the time period tt1 is increased or decreased by three minutes, and the time period tt2 is increased or decreased by three minutes. In this case, there are formed nine condition patterns including a pattern in which neither time period tt1 nor tt2 is varied. For these nine conditions, a second relationship between temperature and film thickness is derived, and a set temperature or the like is determined (redetermined).

FIG. 6 shows the nine combinations of the set time periods. In the pattern 0, none of the set temperatures T1 to T3 is varied. In the patterns a to h, one of the set temperatures T2 and T3 is varied.

Contents of variation of the set time periods (which of the set temperatures T1 to T3 is varied (entirely varied or partially varied), and changing widths of the respective set temperatures T1 to T3) may be previously determined, and the contents may be stored in the storage device of the control part 120. Alternatively, a user may suitably input the contents in response to a query from the substrate processing apparatus 100. Further, a user may suitably input whether the set time period is varied or not.

In the above embodiment, based on the fact that the expected film thickness D1ij is within the allowable range or not, whether the set time periods tt1 to tt3 are varied or not is determined (judged). However, the following manner is also possible in place thereof. Namely, the number of times for changing the set time periods tt1 to tt3 is preset, and the expected film thickness D1ij is calculated the preset number of times. Then, there is selected a combination of the set temperatures T1 to T3 and the set time periods tt1 to tt3 which can provide optimum uniformity of film thickness.

### G. Process of Substrate (Wafer W) (Step S18)

Based on the set temperature Tkl, wafers W are processed. Namely, the wafers W are loaded into the substrate processing part 110, and the wafers W are subjected to a heat process (film deposition process) in accordance with the set temperature profile shown in FIG. 2(C).

H. Judgment of Whether Measured Film Thickness is within Allowable Range or Not (Step S19)

Film thicknesses of the processed wafer W are measured. When the measured film thicknesses are not within the allowable range, the process of the steps S12 to S19 is repeated. At this time, the deriving step of deriving a table showing the relationship between temperature and film thickness (step S12) may be omitted depending on cases (for example, when the table showing the relationship between temperature and film thickness is not largely changed). For example, there may be a case in which the calculation is performed again without any influence being exerted to the table showing the relationship between temperature and film thickness, or a case in which the learning function is added to the step S14.

### OTHER EMBODIMENT

The above-described embodiment may be extended or modified within a scope of the concept of the present invention. The substrate is not limited to a semiconductor wafer, but may be a glass substrate. The number of dividing the heater is not limited to five.

1. A substrate processing apparatus comprising:
a storage part that stores a set temperature profile including:
a first step in which a temperature is varied from a first temperature to a second temperature during a first time period;
a second step in which the temperature is maintained at the second temperature during a second time period; and
a third step in which the temperature is varied from the second temperature to a third temperature;
a substrate processing part that deposits a film on a substrate, by heating the substrate in accordance with the set temperature profile and by supplying a process gas in the third step;
a first derivation part that derives a first relationship between temperature and film thickness which is a corresponding relationship between a variation amount of temperature and variation amounts of film thicknesses at a plurality of positions on a substrate, when the substrate is processed in accordance with a varied temperature profile in which at least one of the first temperature, the second temperature, and the third temperature is varied;
an input part to which measured film thicknesses at the plurality of positions on the substrate that has been actually processed by the substrate processing part in accordance with a predetermined set temperature profile are inputted;
a first determination part that determines the first temperature, the second temperature, and the third temperature, based on the first relationship between temperature and film thickness, the measured film thicknesses at the plurality of positions, and a predetermined target film thickness;
an expected film-thickness calculation part that calculates expected film thicknesses at a plurality of positions on a substrate to be actually processed in accordance with the set temperature profile corresponding to the determined first temperature, the determined second temperature, and the determined third temperature;
a second derivation part that varies at least one of the first time period, the second time period, and the third time period, under predetermined circumstances, and that derives a second relationship between temperature and film thickness which is a corresponding relationship between a variation amount of temperature and variation amounts of film thicknesses at the plurality of positions on the substrate, when the substrate is processed in accordance with a further varied temperature profile in which one of the first temperature, the second temperature, and the third temperature is varied; and
a second determination part that redetermines the first temperature, the second temperature, and the third temperature, based on the second relationship between temperature and film thickness, the measured film thicknesses at the plurality of positions, and the predetermined target film thickness.

2. The substrate processing apparatus according to claim 1, wherein
the predetermined circumstances are circumstances in which the expected film thicknesses at the plurality of positions are not within a predetermined allowable range with respect to the predetermined target film thickness.

3. The substrate processing apparatus according to claim 1, wherein:
the storage part stores a plurality of set temperature profiles; and
the substrate processing part includes a holding part that can hold a plurality of substrate in a tier-like manner, and a plurality of heating parts whose heat values can be controlled in accordance with the respective set temperature profiles.

4. The substrate processing apparatus according to claim 3, wherein:
the first derivation part is configured to derive the first relationship between temperature and film thickness which is a corresponding relationship between a variation amount of temperature and variation amounts of film thicknesses at a plurality of positions on a substrate, when the substrate is processed in accordance with a plurality of varied temperature profiles in any of which at least one of the first temperature, the second temperature, and the third temperature is varied;
the input part is configured such that measured film thicknesses at the plurality of positions on a plurality of substrates respectively corresponding to the plurality of heating parts are inputted, the substrates having been actually processed by the substrate processing part in accordance with the plurality of predetermined set temperature profiles; and
the first determination part is configured to determine the first temperature, the second temperature, and the third temperature of each of the plurality of set temperature profiles, based on the first relationship between temperature and film thickness, the measured film thicknesses at the plurality of positions on the plurality of substrates; and the predetermined target film thickness.

5. The substrate processing apparatus according to claim 1, wherein
the first derivation part includes:
a first calculation part that calculates first expected film thicknesses at the plurality of positions, when the substrate is processed in accordance with a set temperature profile in which the first temperature is varied;
a second calculation part that calculates second expected film thicknesses at the plurality of positions, when the substrate is processed in accordance with another set temperature profile in which the second temperature is varied;
a third calculation part that calculates third expected film thicknesses at the plurality of positions, when the substrate is processed in accordance with another set temperature profile in which the third temperature is varied;
a fourth calculation part that calculates fourth expected film thicknesses at the plurality of positions, when the substrate is processed in accordance with the original set temperature profile in which none of the temperatures is varied; and
a difference calculation part that calculates a difference between each of the first to third expected film thicknesses and the fourth expected film thicknesses.

6. A method of controlling a substrate processing apparatus that deposits a film on a substrate by heating the substrate in accordance with a set temperature profile including: a first step in which a temperature is varied from a first temperature to a second temperature during a first time period; a second step in which the temperature is maintained at the second temperature during a second time period; and a third step in which the temperature is varied from the second temperature to a third temperature; and by supplying a process gas in the third step, the method comprising the steps of:
deriving a first relationship between temperature and film thickness which is a corresponding relationship between a variation amount of temperature and variation amounts of film thicknesses at a plurality of positions on a substrate, when the substrate is processed in accordance with a varied temperature profile in which at least one of the first temperature, the second temperature, and the third temperature is varied;
inputting measured film thicknesses at the plurality of positions on the substrate that has been actually processed in accordance with the predetermined set temperature profile;
determining the first temperature, the second temperature, and the third temperature, based on the first relationship between temperature and film thickness, the measured film thicknesses at the plurality of positions, and a predetermined target film thickness;
calculating expected film thicknesses at a plurality of positions on a substrate to be actually processed in accordance with the set temperature profile corresponding to the determined first temperature, the determined second temperature, and the determined third temperature;
varying at least one of the first time period, the second time period, and the third time period, under predetermined circumstances, and then deriving a second relationship between temperature and film thickness which is a corresponding relationship between a variation amount of temperature and variation amounts of film thicknesses at the plurality of positions on the substrate, when the substrate is processed in accordance with a further varied temperature profile in which one of the first temperature, the second temperature, and the third temperature is varied; and
redetermining the first temperature, the second temperature, and the third temperature, based on the second relationship between temperature and film thickness, the measured film thicknesses at the plurality of positions, and the predetermined target film thickness.

7. The method of controlling a substrate processing apparatus according to claim 6, wherein
the predetermined circumstances are circumstances in which the expected film thicknesses at the plurality of positions are not within a predetermined allowable range with respect to the predetermined target film thickness.

8. A storage medium storing a computer program operable on a computer, the computer program including steps to implement the method of controlling a substrate processing apparatus according to claim 6.
